(19) United States
(12) Patent Application Publication
(10) Pub. No.: US 2021/0217456 A1
(43) Pub. Date: Jul. 15, 2021

(54) MEMORY DEVICE AND METHOD OF OPERATING THE SAME

(71) Applicant: SK hynix Inc., Icheon-si Gyeonggi-do (KR)

(72) Inventors: Gil Bok CHOI, Icheon-si Gyeonggi-do (KR); Moon Sik SEO, Icheon-si Gyeonggi-do (KR)

(73) Assignee: SK hynix Inc., Icheon-si Gyeonggi-do (KR)

(21) Appl. No.: 16/922,385

(22) Filed: Jul. 7, 2020

(30) Foreign Application Priority Data
Jan. 15, 2020 (KR) 10-2020-0005563

(51) Int. Cl. G11C 11/4074; G11C 11/406; G11C 11/4076; G11C 11/4094; G11C 11/408

(52) U.S. Cl. CPC G11C 11/4074; G11C 11/40626; G11C 11/4085; G11C 11/4094; G11C 11/4076

(57) ABSTRACT

A memory device, and a method of operating the memory device, includes: a memory cell array including a plurality of strings; a voltage generation circuit configured to apply a turn-on voltage to the plurality of strings during a set application period in a channel initialization operation of a read operation of a selected string among the plurality of strings; a temperature detection circuit configured to measure an internal temperature of the memory device and generate a temperature signal; and control logic configured to control the voltage generation circuit to set the application period in response to the temperature signal and apply the turn-on voltage to the plurality of strings during the set application period.

### CROSS-REFERENCE TO RELATED APPLICATION

The present application claims priority under 35 U.S.C. § 119(a) to Korean patent application number 10-2020-0005563, filed on Jan. 15, 2020, in the Korean Intellectual Property Office, the entire disclosure of which is incorporated herein by reference.

### BACKGROUND

### 1. Technical Field

Various embodiments of the present disclosure relate to an electronic device, and more particularly, to a memory device and a method of operating the memory device.

### 2. Related Art

Recently, a paradigm shift to ubiquitous computing means that computer systems are accessible virtually anytime and anywhere. Thereby, the use of portable electronic devices such as mobile phones, digital cameras, and notebook computers has rapidly increased. In general, such portable electronic devices use a memory system which employs a memory device, in other words, uses a data storage device. The data storage device can be used as a main memory device and/or an auxiliary memory device of the portable electronic devices.

A data storage device using a memory device provides advantages in that, because there is no mechanical driving part, stability and durability are excellent, information access speed is increased, and power consumption is reduced. Examples of a data storage device proposed for a memory system having such advantages may include a universal serial bus (USB) memory device, a memory card having various interfaces, and a solid state drive (SSD).

The memory devices are classified as volatile memory devices or nonvolatile memory devices.

Although read and write speeds are comparatively low, a nonvolatile memory device can retain data stored even when a power supply is interrupted. Therefore, a nonvolatile memory device is used when there is the need for storing data which must be maintained regardless of supplied power. Representative examples of a nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memory is classified as a NOR type or a NAND type.

### SUMMARY

An embodiment of the present disclosure may provide for a memory device including: a memory cell array including a plurality of strings; a voltage generation circuit configured to apply a turn-on voltage to the plurality of strings during a set application period in a channel initialization operation of a read operation of a selected string among the plurality of strings; a temperature detection circuit configured to measure an internal temperature of the memory device and generate a temperature signal; and control logic configured to control the voltage generation circuit to set the application period in response to the temperature signal and apply the turn-on voltage to the plurality of strings during the set application period.

An embodiment of the present disclosure may provide for a memory device including: a memory cell array including a plurality of strings; a temperature detection circuit configured to detect an internal temperature of the memory device and generate a temperature signal; a voltage generation circuit configured to apply a turn-on voltage to select lines of a selected string and an unselected string of the plurality of strings during a channel initialization operation of a read operation; and control logic configured to control, during the channel initialization operation, the voltage generation circuit to apply the turn-on voltage to the select lines of the selected string during a fixed application time, and apply the turn-on voltage to the select lines of the unselected strings during a variable time. The control logic may be configured to vary an application time of the turn-on voltage to be applied to the unselected strings in response to the temperature signal.

An embodiment of the present disclosure may provide for a method of operating a memory device, the method including: measuring an internal temperature of the memory device; setting a turn-on voltage application period of a channel initialization operation based on the measured internal temperature; applying a turn-on voltage to select transistors of an unselected string among a plurality of strings during the set turn-on voltage application period; and applying a pass voltage to word lines of the plurality of strings.

### BRIEF DESCRIPTION OF THE DRAWINGS

FIG. 1 is a block diagram illustrating a memory device in accordance with an embodiment of the present disclosure.

FIG. 2 is a diagram illustrating memory blocks each having a three-dimensional structure.

FIG. 3 is a circuit diagram for describing in detail any one of the memory blocks illustrated in FIG. 2.

FIG. 4 is a circuit diagram illustrating strings shown in FIG. 3.

FIG. 5 is a diagram illustrating control logic of FIG. 1.

FIG. 6 is a flowchart of a method of operating a memory device in accordance with an embodiment of the present disclosure.

FIG. 7 is a waveform diagram of operating voltages for describing the method of operating the memory device in accordance with an embodiment of the present disclosure.

FIGS. 8 and 9 are sectional views of a string for describing a method of operating the memory device in accordance with an embodiment of the present disclosure.

FIG. 10 is a block diagram illustrating a memory system including the memory device of FIG. 1.

FIG. 11 is a diagram illustrating a memory system in accordance with an embodiment of the present disclosure.

FIG. 12 is a diagram illustrating a memory system in accordance with an embodiment of the present disclosure.

FIG. 13 is a diagram illustrating a memory system in accordance with an embodiment of the present disclosure.

FIG. 14 is a diagram illustrating a memory system in accordance with an embodiment of the present disclosure.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

The present disclosure will now be described in detail based on embodiments. The present disclosure may, however, be embodied in many different forms and should not be construed as being limited to only the embodiments set forth herein, but should be construed as covering modifications, equivalents, or alternatives falling within ideas and technical scopes of the present disclosure. However, it is to be understood that the present description is not intended to limit the present disclosure to those embodiments, and the present disclosure is intended to cover not only the embodiments, but also various alternatives, modifications, equivalents, and other embodiments that fall within the spirit and scope of the present disclosure.

Various embodiments of the present disclosure will now be described more fully hereinafter with reference to the accompanying drawings, in which embodiments of the present disclosure are shown, so that those of ordinary skill in the art can carry out the technical idea of the present disclosure.

Some embodiments of the present disclosure are directed to a memory device capable of improving electrical characteristics during a read operation. Additional embodiments are directed to a method of operating the memory device.

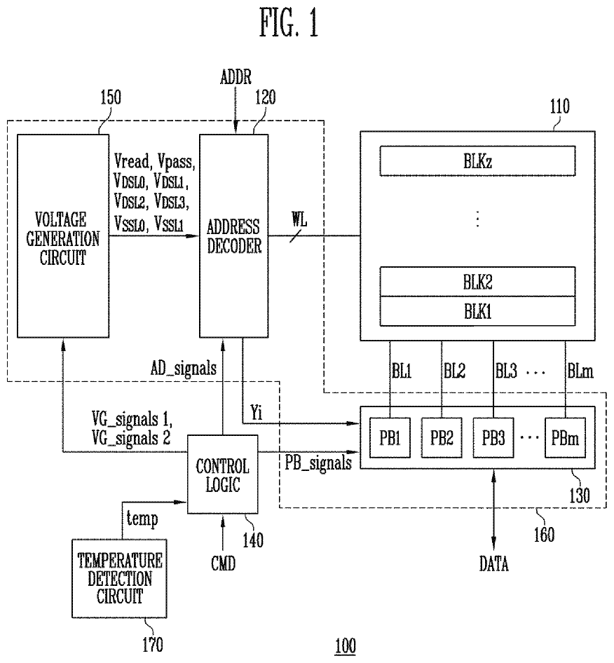

FIG. 1 is a block diagram illustrating a memory device 100 in accordance with an embodiment of the present disclosure.

Referring to FIG. 1, the memory device 100 may include a memory cell array 110, an address decoder 120, a read/write circuit 130, control logic 140, a voltage generation circuit 150, and a temperature detection circuit 170. The address decoder 120, the read/write circuit 130, and the voltage generation circuit 150 may be defined as a peripheral circuit 160 configured to perform a program operation on the memory cell array 110.

The memory cell array 110 may include a plurality of memory blocks BLK1 to BLKz. The plurality of memory blocks BLK1 to BLKz are coupled to the address decoder 120 through word lines WL. The memory blocks BLK1 to BLKz may be coupled to the read/write circuit 130 through bit lines BL1 to BLm. Each of the memory blocks BLK1 to BLKz may include a plurality of memory cells. In an embodiment, the plurality of memory cells may be nonvolatile memory cells. Memory cells coupled to one word line among the plurality of memory cells may be defined as one page. In other words, the memory cell array 110 may be formed of a plurality of pages.

Each of the memory blocks BLK1 to BLKz of the memory cell array 110 may include a plurality of strings. Each of the strings may include a drain select transistor, a plurality of memory cells, and a source select transistor which are coupled in series between a bit line and a source line. Furthermore, each of the plurality of strings may include pass transistors respectively provided between the source select transistor and the memory cells and between the drain select transistor and the memory cells, and may further include a pipe gate transistor between the memory cells. The memory cell array 110 will be described in detail later herein.

The address decoder 120 may be coupled to the memory cell array 110 through the word lines WL, The address decoder 120 may be operated in response to address decoder control signals AD_signals generated from the control logic 140. The address decoder 120 may receive addresses ADDR through an input/output buffer (not shown) provided in the memory device 100.

During a read operation, the address decoder 120 may apply a plurality of operating voltages including a read voltage Vread, a pass voltage Vpass, a plurality of drain select line voltages V_{DSL0}, V_{DSL1}, V_{DSL2}, and V_{DSL3}, and a plurality of source select line voltage V_{SSL0} and V_{SSL1} that are generated from the voltage generation circuit 150, to a plurality of memory cells, drain select transistors, and source select transistors of the memory cell array 110 in response to a decoded row address obtained by decoding a row address of the received addresses ADDR.

The address decoder 120 may adjust an application period of a turn-on voltage to be applied to the drain select line and the source select line of an unselected string in response to the address decoder control signals AD_signals during a channel initialization operation of the read operation.

The address decoder 120 may decode a column address among addresses ADDR received during a read operation. The address decoder 120 may transmit the decoded column address Yi to the read/write circuit 130.

Addresses ADDR received during the read operation may include a block address, a row address, and a column address. The address decoder 120 may select one memory block and one word line based on the block address and the row address. The column address may be decoded by the address decoder 120 and provided to the read/write circuit 130.

The address decoder 120 may include a block decoder, a row decoder, a column decoder, an address buffer, etc.

The read/write circuit 130 may include a plurality of page buffers PB1 to PBm. The plurality of page buffers PB1 to PBm may be coupled to the memory cell array 110 through the bit lines BL1 to BLm. During a precharge operation of the read operation, the plurality of page buffers PB1 to PBm may respectively precharge the bit lines BL1 to BLm to a preset level. During a read voltage application operation, the plurality of page buffers PB1 to PBm may respectively sense potential levels or currents of the bit lines BL1 to BLm to perform the read operation.

The read/write circuit 130 may operate in response to page buffer control signals PB_signals output from the control logic 140.

In an embodiment, the read/write circuit 130 may include page buffers (or page registers), a column select circuit, etc.

The control logic 140 may be implemented as hardware, software, or a combination of hardware and software. For example, the control logic 140 may be a control logic circuit operating in accordance with an algorithm and/or a processor executing control logic code.

The control logic 140 may be coupled to the address decoder 120, the read/write circuit 130, and the voltage generation circuit 150. The control logic 140 may receive a command CMD through an input/output buffer (not shown) of the memory device 100. The control logic 140 may control the overall operation of the memory device 100 in response to the command CMD. For example, the control logic 140 may receive a command CMD corresponding to a read operation, and then generate and output, in response to the received command CMD, address decoder control signals AD_signals for controlling the address decoder 120, page buffer control signals PB_signals for controlling the read/write circuit 130, and voltage generation circuit control signals VG_signals 1 and VG_signals 2 for controlling the voltage generation circuit 150.

The control logic 140, in accordance with an embodiment of the present disclosure, may receive a temperature signal temp from the temperature detection circuit 170, and set an application period of a turn-on voltage to be applied to the drain select transistors and the source select transistors of unselected strings in response to the received temperature signal temp during a channel initialization operation of the read operation. The control logic 140 may generate and output address decoder control signals AD_signals in which the application period of the turn-on voltage corresponding to the set unselected strings is reflected. For example, if it is determined that an internal temperature of the memory device 100 is relatively high based on the temperature signal temp received from the temperature detection circuit 170, the control logic 140 may set the application period of the turn-on voltage corresponding to the unselected strings to a relatively short period. If it is determined that the internal temperature of the memory device 100 is relatively low, the control logic 140 may set the application period of the turn-on voltage corresponding to the unselected strings to a relatively long period. Thereby, in the case where the internal temperature of the memory device 100 is relatively low, a turn-on voltage may be applied to the drain select transistor and the source select transistor of an unselected string for a sufficient time so that hot carries that remain in the channel can be effectively removed. In the case where the internal temperature of the memory device 100 is relatively high, the turn-on voltage may be applied to the drain select transistor and the source select transistor of the unselected string for a relatively short time so that the read characteristics of the memory block can be improved.

During the read operation, the voltage generation circuit 150 may generate a plurality of operating voltages including a read voltage Vread, a pass voltage Vpass, a plurality of drain select line voltages V_{DSL0}, V_{DSL1}, V_{DSL2}, and V_{DSL3} and a plurality of source select line voltages V_{SSL0}, and V_{SSL1} in response to voltage generation circuit control signals VG_signals 1 and VG_signals 2 output from the control logic 140, and output the plurality of operating voltages to the address decoder 120. The plurality of drain select line voltages V_{DSL0}, V_{DSL1}, V_{DSL2}, and V_{DSL3} and the plurality of source select line voltages V_{SSL0} and V_{SSL1} may be turn-on voltages to be applied during the channel initialization operation.

During the read operation of the memory device 100, the temperature detection circuit 170 may measure the internal temperature of the memory device 100 and generate and output a temperature signal temp corresponding to the measured temperature value. In other words, the temperature signal temp may include information about the internal temperature of the memory device 100.

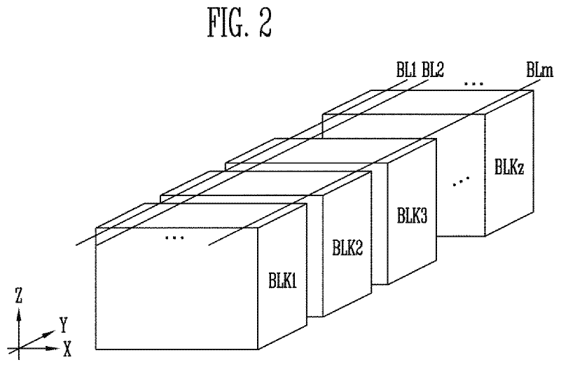

FIG. 2 is a diagram illustrating memory blocks each having a three-dimensional structure.

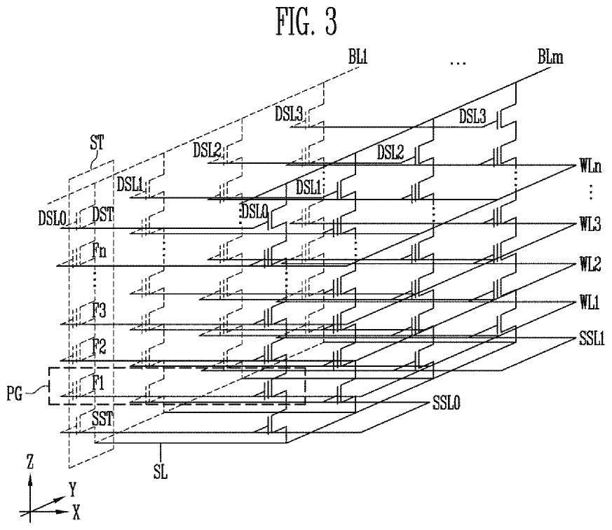

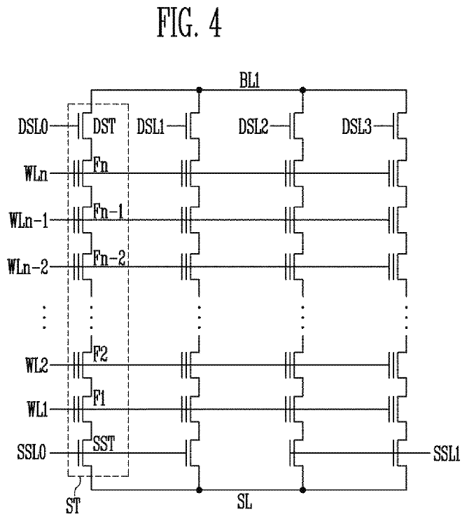

Referring to FIG. 2, the memory blocks BLK1 to BLKz each having a three-dimensional structure may be arranged at positions spaced apart from each other in a direction Y in which bit lines BL1 to BLm extend. For example, the first to z-th memory blocks BLK1 to BLKz may be arranged at positions spaced apart from each other in a second direction Y, and each may include a plurality of memory cells stacked in a third direction Z. Hereinbelow, the configuration of any one memory block of the first to z-th memory blocks BLK1 to BLKz will be described in detail with reference to FIGS. 3 and 4.

FIG. 3 is a circuit diagram for describing in detail any one of the memory blocks illustrated in FIG. 2.

FIG. 4 is a circuit diagram illustrating strings shown in FIG. 3.

Referring to FIGS. 3 and 4, each string ST may be coupled between the bit line BL1 to BLm and a source line SL. The string ST coupled between the first bit line BL1 and the source line SL will be described below by way of example.

The string ST may include a source select transistor SST, memory cells F1 to Fn (n is a positive integer), and a drain select transistor DST, which are coupled to each other in series between the source line SL and the first bit line BL1. Gates of the source select transistors SST included in different strings ST coupled to the respective bit lines BL1 to BLm may be coupled to a first source select line SSL0 or a second source select line SSL1. For example, source select transistors disposed adjacent to each other in the second direction Y among the source select transistors SST may be coupled to the same source select line. For example, when it is assumed that the source select transistors SST are successively arranged in the second direction Y, the gates of the source select transistors SST that are arranged in the first direction X from the first source select transistor SST and included in different strings ST and the gates of the source select transistors SST that are arranged in the first direction X from the second source select transistor SST and included in different strings ST may be coupled to the first source select line SSL0. Furthermore, the gates of the source select transistors SST that are arranged in the first direction X from the third source select transistor SST and included in different strings ST and the gates of the source select transistors SST that are arranged in the first direction X from the fourth source select transistor SST and included in different strings ST may be coupled to the second source select line SSL1.

Gates of the memory cells F1 to Fn may be coupled to the word lines WL1 to WLn, and gates of the drain select transistors DST may be coupled to any one of the first to fourth drain select lines DSL0 to DSL3.

Although the gates of the transistors that are arranged in the first direction X among the drain select transistors DST are coupled in common to the same drain select line (e.g., DSL0), the transistors that are arranged in the second direction Y may be coupled to different drain select lines DSL1 to DSL3. For example, if it is assumed that the drain select transistors DST are successively arranged in the second direction Y, the gates of the drain select transistors DST that are arranged in the first direction X from the first drain select transistor DST and included in different strings ST may be coupled to the first drain select line DSL0. The drain select transistors DST that are arranged in the second direction Y from the drain select transistors DST coupled to the first drain select line DSL0 may be successively coupled to the second to fourth drain select lines DSL1 to DSL3. Therefore, in a selected memory block, strings ST coupled to a selected drain select line may be selected, and strings ST coupled to the other unselected drain select lines may be unselected.

Memory cells coupled to the same word line may form one page PG. Here, the term “page” means a physical page. For example, a group of memory cells coupled in the first direction X in the same word line among the strings ST coupled to the first to m-th bit line BL1 to BLm may be referred to as “page PG”. For example, the memory cells that are arranged in the first direction X among the first memory cells F1 coupled to the first word line WL1 may form one page PG. Cells arranged in the second direction Y among the first memory cells F1 coupled in common to the first word line WL1 may be separated from each other by different pages. Therefore, in the case where the first drain select line DSL0 is a selected drain select line and the first word line WL1 is a selected word line, the page that is coupled to the first drain select line DSL0 among the plurality of pages PG coupled to the first word line WL1 may become a selected page. The pages that are coupled in common to the first word line WL1 and coupled to the unselected second to fourth drain select lines DSL1 to DSL3 may become unselected pages.

Although in the drawing there is illustrated the case where one source select transistor SST and one drain select transistor DST are included in each string ST, a plurality of source select transistors SST and a plurality of drain select transistors DST may be included in each string ST depending on the configuration of the memory device. Furthermore, depending on the configuration of the memory device, dummy cells may be provided between the source select transistor SST, the memory cells F1 to Fn, and the drain select transistor DST. Unlike the normal memory cells F1 to Fn, the dummy cells might not store user data but may be used to improve electrical characteristics of each string ST. However, in the present embodiment, the dummy cells are not significant components; therefore, detailed description thereof will be omitted.

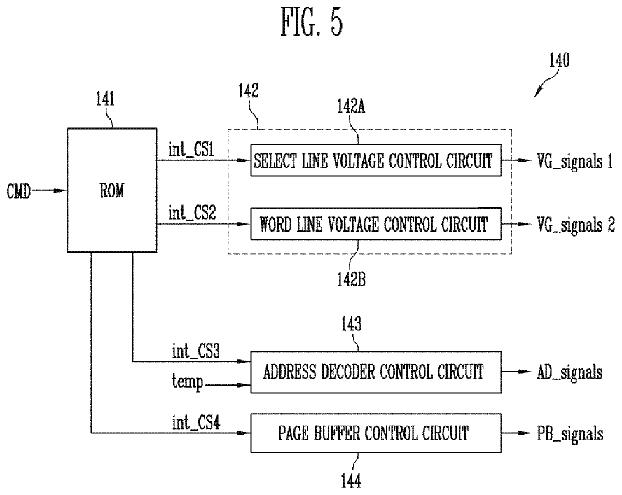

FIG. 5 is a diagram illustrating the control logic 140 of FIG. 1.

Referring to FIG. 5, the control logic 140 may include a ROM 141, a voltage generation control circuit 142, an address decoder control circuit 143, and a page buffer control circuit 144.

The ROM 141 may store therein an algorithm for performing the overall operation of the memory device, and generate a plurality of internal control signals int_CS1 to int_CS4 in response to a command CMD input from an external device, e.g., a host coupled with the memory device.

The voltage generation control circuit 142 may include a select line voltage control circuit 142A and a word line voltage control circuit 142B. The select line voltage control circuit 142A may generate first voltage generation circuit signals VG_signals 1 for controlling the voltage generation circuit 150 of FIG. 1 to generate select line voltages V_{DSL0}, V_{DSL1}, V_{DSL2}, V_{DSL3}, V_{DSL0}, V_{SSL0}, and V_{SSL1} to be applied to a selected memory block during a read operation of the memory device in response to the internal control signal int_CS1. The word line voltage control circuit 142B may generate second voltage generation circuit signals VG_signals 2 for controlling the voltage generation circuit 150 of FIG. 1 to generate a read voltage Vread and a pass voltage Vpass to be applied to the selected memory block during the read operation of the memory device in response to the internal control signal int_CS2.

During the overall operation of the memory device, the address decoder control circuit 143 may output, in response to the internal control signal int_CS3, address decoder control signals AD_signals for controlling the address decoder 120 of FIG. 1. During the channel initialization operation of the read operation, the address decoder control circuit 143 may set, in response to the temperature signal temp, an application period of turn-on voltage to be applied to drain select lines and source select lines coupled to unselected strings, and generate and output address decoder control signals AD_signals in which the set application period of the turn-on voltage corresponding to the unselected strings is reflected.

During the overall operation of the memory device, the address decoder control circuit 144 may output, in response to the internal control signal int_CS4, page buffer control signals PB_signals for controlling the read and write circuit 130 of FIG. 1.

FIG. 6 is a flowchart of a method of operating the memory device in accordance with an embodiment of the present disclosure.

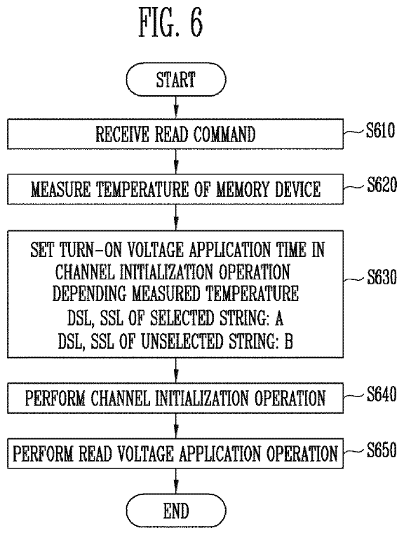

FIG. 7 is a waveform diagram of operating voltages for describing the method of operating the memory device in accordance with an embodiment of the present disclosure.

The method of operating the memory system in accordance with an embodiment of the present disclosure will be described with reference to FIGS. 1 to 7.

A command CMD corresponding to a read operation and an address ADDR corresponding to memory cells on which the read operation is to be performed may be received from an external device to the memory device 100 (at step S610).

The memory device 100 may select one of the plurality of memory blocks BLK1 to BLKz included in the memory cell array 110 in response to the received command CMD and address ADDR, and select a page and string on which a read operation of a selected memory block (e.g., BLK1) is to be performed.

In an embodiment of the present disclosure, there will be described an example in which a string ST corresponding to the first drain select line DSL0 may be a selected string, and strings ST corresponding to the other second to fourth drain select lines DSL1 to DSL3 are unselected strings.

During the read operation of the memory device 100, the temperature detection circuit 170 may measure the internal temperature of the memory device 100 and generate and output a temperature signal temp corresponding to the measured temperature value (at step S620). In other words, the temperature signal temp may include information about the internal temperature of the memory device 100.

During a channel initialization operation t1 of the read operation, the control logic 140 may set an application period A of a turn-on voltage Vturn_on to be applied to the drain select transistor DST and the source select transistor SST of a selected string, and an application period B of a turn-on voltage Vturn_on to be applied to a drain select transistor DST and a source select transistor SST of an unselected string (at step S630). The application period B of the turn-on voltage Vturn_on to be applied to the drain select transistor DST and the source select transistor SST of the unselected string may be set to be variable depending on the internal temperature of the memory device 100. In other words, the control logic 140 may set the application period B of the turn-on voltage Vturn_on to be applied to the drain select transistor DST and the source select transistor SST of the unselected string based on the temperature signal temp, For example, if it is determined that the internal temperature of the memory device 100 is relatively high based on the temperature signal temp received from the temperature detection circuit 170, the control logic 140 may set the application period B of the turn-on voltage corresponding to the unselected strings to a relatively short period. If it is determined that the internal temperature of the memory device 100 is relatively low, the control logic 140 may set the application period B of the turn-on voltage corresponding to the unselected strings to a relatively long period. The turn-on voltage Vturn_on may be a voltage at which the drain select transistors DST and the source select transistors SST are turned on, in other words, a voltage higher than the threshold voltages of the drain select transistors DST and the source select transistors SST.

The memory device 100 may perform a channel initialization operation t1 of the read operation (at step S640). For example, the voltage generation circuit 150 may generate a turn-on voltage Vturn_on under the control of first voltage generation control signals VG_signals 1 output from the control logic 140, and output the turn-on voltage Vturn_on as a plurality of drain select line voltages V_{DSL0}, V_{DSL1}, V_{DSL2}, and V_{DSL3} and a plurality of source select line voltages V_{SSL0} and V_{SSL1}. Here, the voltage generation circuit 150 may generate an operating voltage to be applied to the word lines WL1 to WLn under the control of the second voltage generation control signals VG_signals 2, and output the operating voltage as a pass voltage Vpass. The pass voltage Vpass may have the same potential level as that of the turn-on voltage Vturn_on.

The address decoder 120 may apply, to the selected memory block BLK1, the plurality of drain select line voltages V_{DSL0}, V_{DSL1}, V_{DSL2}, and V_{DSL3} and the plurality of source select line voltages V_{SSL0}, and V_{SSL1} that have the turn-on voltage (Vturn_on) level and have been generated from the voltage generation circuit 150. Here, in response to the address decoder control signals AD_signals, the address decoder 120 may apply, during the set application period B, the drain select line voltages V_{DSL1}, V_{DSL2}, and V_{DSL3} and the source select line voltage V_{SSL1} that have the turn-on voltage (Vturn_on) level to the second to fourth drain select lines DSL1 to DSL3 and the second source select line SSL1 that correspond to the unselected strings, and apply, during the application period A, the first drain select line voltage V_{DSL0} and the first source select line voltage V_{SSL0} that have the turn-on voltage (Vturn_on) level to the first drain select line ASL0 and the first source select line SSL0 that correspond to the selected string.

The address decoder 120 may apply the pass voltage Vpass generated from the voltage generation circuit 150 to the word lines of the selected memory block BLK1. Here, the address decoder 120 may apply the pass voltage Vpass to the unselected word lines Unsel WL and, thereafter, apply the pass voltage Vpass to the selected word line Sel WL. The address decoder 120 may perform an operation of applying the turn-on voltage Vturn-on to the drain select lines and the source select lines of the selected memory block BLK1 and, thereafter, perform an operation of applying the pass voltage Vpass to the word lines.

As the turn-on voltage Vturn-on and the pass voltage Vpass are applied to the drain select lines, the source select lines, and the word lines of the selected memory block BLK1, hot holes that remain in the channels of the strings ST included in the selected memory block BLK1 may be removed through the source line SL.

The memory device 100 may perform a read voltage application operation t2 of the read operation (at step S650).

For example, the voltage generation circuit 150 and the address decoder 120 may discharge the pass voltage Vpass applied to the selected word line Sel WL while maintaining the pass voltage Vpass applied to the unselected word lines Unsel WL. Furthermore, the voltage generation circuit 150 and the address decoder 120 may discharge the turn-on voltage Vturn-on applied to the first drain select line DSL0 and the first source select line SSL0 that correspond to the selected string, and discharge the turn-on voltage Vturn-on applied to the second to fourth drain select lines DSL1 to DSL3 and the second source select line SSL1 that correspond to the unselected strings.

Subsequently, the voltage generation circuit 150 may generate a read voltage Vread and a pass voltage Vpass to be applied to the word lines WL1 to WLn of the selected memory block in response to the second voltage generation circuit control signals VG_signals 2. In response to the address decoder control signals AD_signals and the address ADDR, the address decoder 120 may apply the pass voltage Vpass to the unselected word lines Unsel WL and apply the read voltage Vread to the selected word line Sel WL. Here, the turn-on voltage Vturn_on may be applied to the drain select transistor DST and the source select transistor SST that correspond to the selected string ST.

The read and write circuit 130 may perform a read operation by sensing the potential levels or current levels of the bit lines BL1 to BLm in response to the page buffer control signals PB_signals.

In an embodiment of the present disclosure, although there is illustrated the case where, during the period t2, the turn-on voltage Vturn-on applied to the drain select line and the source select line that correspond to the selected string a period t2 is discharged and thereafter the turn-on voltage Vturn-on is re-applied during the read voltage application operation, the turn-on voltage Vturn-on may be continuously applied to the drain select line and the source select line without being discharged.

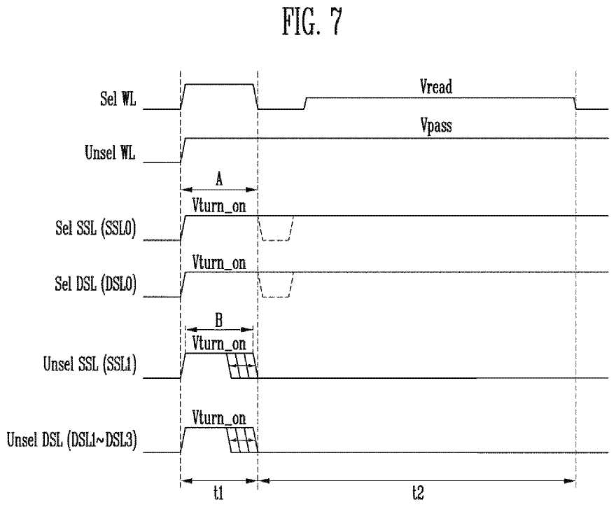

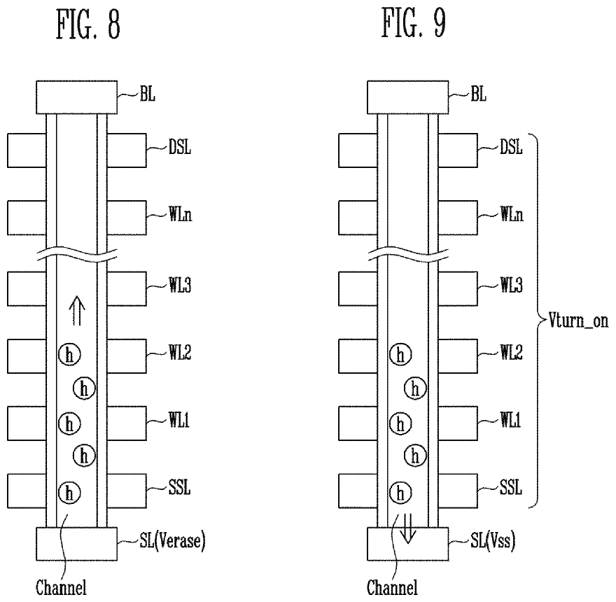

FIGS. 8 and 9 are sectional views of a string for describing a method of operating the memory device in accordance with an embodiment of the present disclosure.

FIG. 8 illustrates one of a plurality of strings included in an unselected memory block during an erase operation. The plurality of memory blocks BLK1 to BLKz described with reference to FIGS. 1 to 3 may share the source line SL. Thereby, during an erase operation of a selected memory block of the plurality of memory blocks BLK1 to BLKz, hot holes \textcircled{h} may be drawn into the channel of each of the strings included in the unselected memory blocks by an erase voltage Verase.

FIG. 9 illustrates one of the plurality of strings included in the selected memory block during a channel initialization operation of a read operation. During the channel initialization operation, a turn-on voltage Vturn_on may be applied to the drain select transistor DST, the plurality of memory cells F1 to Fn, and the source select transistor SST of the strings ST included in the selected memory block. Thereby, the drain select transistor DST, the plurality of memory cells F1 to Fn, and the source select transistor SST of the selected memory block may be turned on. The channel of each of the strings ST included in the selected memory block may be coupled with the source line SL having the ground voltage (Vss) level so that hot holes \textcircled{h} may be removed from the channel.

In an embodiment of the present disclosure, during the channel initialization operation, the application period of the turn-on voltage to be applied to the source select transistor and the drain select transistor of each unselected string may be adjusted depending on the temperature. Thereby, at a relatively high temperature, the memory device may set the application period of the turn-on voltage corresponding to the unselected strings to a relatively short period so that the read characteristics of the memory device can be improved. At a relatively low temperature, the memory device may set the application period of the turn-on voltage corresponding to the unselected strings to a relatively long period so that hot carriers remaining in the channels can be effectively removed, whereby a read disturb phenomenon may be improved.

FIG. 10 is a block diagram illustrating a memory system 10000 including a memory device 1100, which for an embodiment is the memory device 100 of FIG. 1.

Referring to FIG. 10, the memory system 10000 may include the memory device 1100 configured to store data, and a memory controller 1200 configured to control the memory device 1100 under the control of a host 2000.

The host 20000 may use, to communicate with the memory system 10000, an interface protocol such as a PCI-E (peripheral component interconnect-express), an ATA (advanced technology attachment), an SATA (serial ATA), a PATA (parallel ATA) or an SAS (serial attached SCSI). In addition, the interface protocol provided for the purpose of data communication between the host 20000 and the memory system 10000 is not limited to the foregoing examples, and it may be any one of interface protocols such as a universal serial bus (USB) protocol, a multi-media card (MMC) protocol, an enhanced small disk interface (ESDI) protocol, and an integrated drive electronics (IDE) protocol.

The memory controller 1200 may control the overall operation of the memory system 10000 and data exchange between the host 20000 and the memory device 1100. For instance, the memory controller 1200 may control the memory device 1100 to program or read data in response to a request of the host 20000. Furthermore, the memory controller 1200 may control the memory device 1100 such that information is stored in main memory blocks and sub-memory blocks included in the memory device 1100, and a program operation is performed on the main memory blocks or the sub-memory blocks depending on the amount of data loaded for the program operation. In an embodiment, the memory device 1100 may include a double data rate synchronous dynamic random access memory (DDR SDRAM), a low power double data rate4 (LPDDR4) SDRAM, a graphics double data rate (GDDR) SDRAM, a low power DDR (LPDDR), a rambus dynamic random access memory (RDRAM), or a flash memory. The configuration and the operation of the memory device 1100 may be the same as those of the memory device 100 of FIG. The memory device 1100 may perform a program operation, a read operation, or an erase operation under the control of the memory controller 1200.

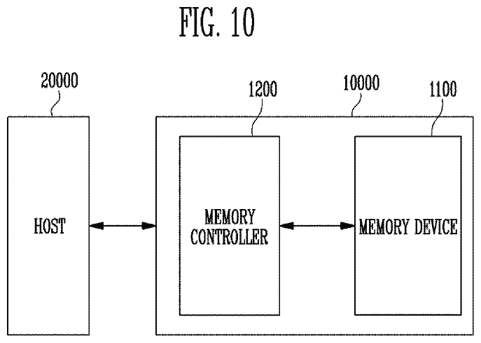

FIG. 11 is a diagram illustrating a memory system 30000 in accordance with an embodiment of the present disclosure.

Referring to FIG. 11, the memory system 30000 may be embodied in a cellular phone, a smartphone, a tablet PC, a personal digital assistant (PDA), or a wireless communication device. The memory system 30000 may include a memory device 1100 and a memory controller 1200 configured to control the operation of the memory device 1100. Under the control of the processor 3100, the memory system 30000 of the memory device 1100 may be embodied in a cellular phone, a smartphone, a tablet PC, a personal digital assistant (PDA), or a wireless communication device. The memory system 30000 may include a memory device 1100 and a memory controller 1200 configured to control the operation of the memory device 1100. The memory controller 1200 may control a data access operation, e.g., a program operation, an erase operation, or a read operation, of the memory device 1100 under the control of a processor 3100.

Data programmed in the memory device 1100 may be outputted through a display 3200 under the control of the memory controller 1200. The configuration and the operation of the memory device 1100 may be the same as those of the memory device 100 of FIG. 1.

A radio transceiver 3300 may send and receive radio signals through an antenna ANT. For example, the radio transceiver 3300 may change a radio signal received through the antenna ANT into a signal capable of being processed in the processor 3100. Therefore, the processor 3100 may process a signal output from the radio transceiver 3300 and transmit the processed signal to the memory controller 1200 or the display 3200. The memory controller 1200 may program a signal processed by the processor 3100 to the memory device 1100. Furthermore, the radio transceiver 3300 may change a signal output from the processor 3100 into a radio signal, and output the changed radio signal to an external device through the antenna ANT. An input device 3400 may be used to input a control signal for controlling the operation of the processor 3100 or data to be processed by the processor 3100. The input device 3400 may be embodied in a pointing device such as a touch pad and a computer mouse, a keypad, or a keyboard. The processor 3100 may control the operation of the display 3200 such that data outputted from the memory controller 1200, data outputted from the radio transceiver 3300, or data outputted form the input device 3400 is outputted through the display 3200.

In an embodiment, the memory controller 1200 capable of controlling the operation of the memory device 1100 may be embodied as a part of the processor 3100 or a chip provided separately from the processor 3100.

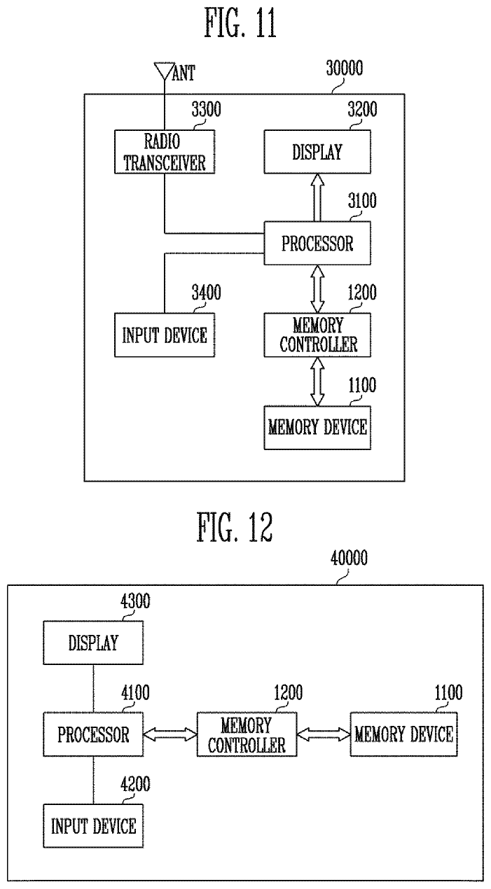

FIG. 12 is a diagram illustrating a memory system 40000 in accordance with an embodiment of the present disclosure.

Referring to FIG. 12, the memory system 40000 may be embodied in a personal computer (PC), a tablet PC, a net-book, an reader, a personal digital assistant (PDA), a portable multimedia player (PMP), an MP3 player, or an MP4 player.

The memory system 40000 may include the memory device 1100 and a memory controller 1200 configured to control the data processing operation of the memory device 1100. The configuration and the operation of the memory device 1100 may be the same as those of the memory device 100 of FIG. 1.

A processor 4100 may output data stored in the memory device 1100 through a display 4300, according to data inputted from an input device 4200. For example, the input device 4200 may be embodied in a pointing device such as a touch pad or a computer mouse, a keypad, or a keyboard.

The processor 4100 may control the overall operation of the memory system 40000 and control the operation of the memory controller 1200. In an embodiment, the memory controller 1200 capable of controlling the operation of the memory device 1100 may be embodied as a part of the processor 4100 or a chip provided separately from the processor 4100.

FIG. 13 is a diagram illustrating a memory system 50000 in accordance with an embodiment of the present disclosure.

Referring to FIG. 13, the memory system 50000 may be embodied in an image processing device, e.g., a digital camera, a portable phone provided with a digital camera, a smartphone provided with a digital camera, or a tablet PC provided with a digital camera.

The memory system 50000 may include a memory device 1100 and a memory controller 1200 capable of controlling a data processing operation, e.g., a program operation, an erase operation, or a read operation, of the memory device 1100. The configuration and the operation of the memory device 1100 may be the same as those of the memory device 100 of FIG. 1.

An image sensor 5200 of the memory system 50000 may convert an optical image into digital signals. The converted digital signals may be transmitted to a processor 5100 or the memory controller 1200. Under the control of the processor 5100, the converted digital signals may be outputted through a display 5300 or stored in the memory device 1100 through the memory controller 1200. Data stored in the memory device 1100 may be outputted through the display 5300 under the control of the processor 5100 or the memory controller 1200.

In an embodiment, the memory controller 1200 capable of controlling the operation of the memory device 1100 may be embodied as a part of the processor 5100 or a chip provided separately from the processor 5100.

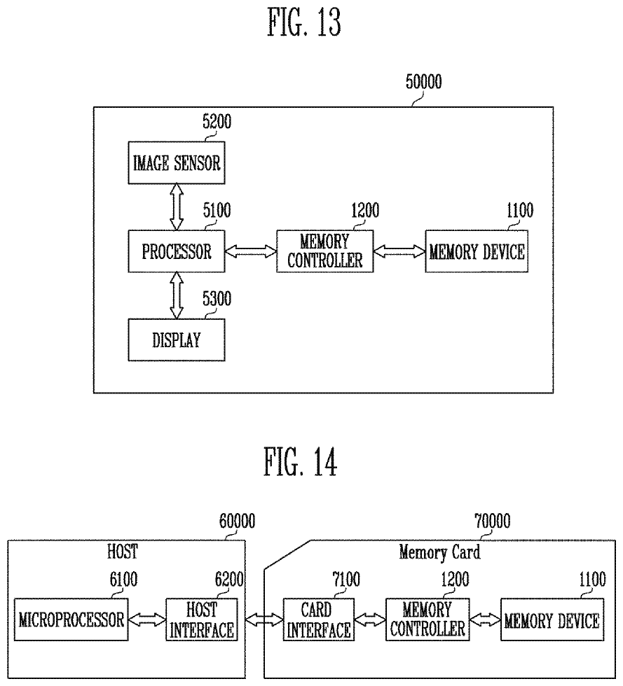

FIG. 14 is a diagram illustrating a memory system 70000 in accordance with an embodiment of the present disclosure.

Referring to FIG. 14, the memory system 70000 may be embodied in a memory card or a smart card. The memory system 70000 may include a memory device 1100, a memory controller 1200, and a card interface 7100. The configuration and the operation of the memory device 1100 may be the same as those of the memory device 100 of FIG. 1.

The controller 1200 may control the data exchange between the memory device 1100 and the card interface 7100. In an embodiment, the card interface 7100 may be a secure digital (SD) card interface or a multi-media card (MMC) interface, but it is not limited thereto.

The card interface 7100 may interface the data exchange between a host 60000 and the memory controller 1200 according to a protocol of the host 60000. In an embodiment, the card interface 7100 may support a universal serial bus (USB) protocol and an interchip (IC)-USB protocol. Here, the card interface may refer to hardware capable of supporting a protocol which is used by the host 60000, software installed in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

In embodiments of the present disclosure, during a read operation of a memory device, hot holes that remain in channels of a selected string and an unselected string may be effectively removed, and a read disturb phenomenon may be mitigated. Consequently, electrical characteristics of the memory device may be improved.

While the embodiments of the present disclosure have been disclosed for illustrative purposes, those skilled in the art will appreciate that various modifications, additions, and substitutions are possible. Therefore, the scope of the present disclosure should be defined by the appended claims and equivalents of the claims rather than by the description preceding them.

Although the embodiments of the present disclosure have been disclosed, those skilled in the art will appreciate that various modifications, additions, and substitutions are possible, without departing from the scope and spirit of the present disclosure.

Therefore, the scope of the present disclosure should be defined by the appended claims and equivalents of the claims rather than by the description preceding them.

In the above-discussed embodiments, all steps may be selectively performed or skipped. In addition, the steps in each embodiment might not be always performed in regular order. Furthermore, the embodiments disclosed in the present specification and the drawings aim to help those with ordinary knowledge in this art more clearly understand the present disclosure rather than aiming to limit the bounds of the present disclosure. In other words, one of ordinary skill in the art to which the present disclosure belongs will be able to understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A memory device comprising:
a memory cell array including a plurality of strings;
a voltage generation circuit configured to apply a turn-on voltage to the plurality of strings during a set application period in a channel initialization operation of a read operation of a selected string among the plurality of strings;
a temperature detection circuit configured to measure an internal temperature of the memory device and generate a temperature signal; and
control logic configured to control the voltage generation circuit to set the application period in response to the temperature signal and apply the turn-on voltage to the plurality of strings during the set application period.

2. The memory device according to claim 1, wherein, based on the temperature signal, the control logic is configured to set the application period to a relatively short period when the internal temperature of the memory device is relatively high, and sets the application period to a relatively long period when the internal temperature of the memory device is relatively low.

3. The memory device according to claim 1, wherein the plurality of strings share one source select line per at least two strings, and the at least two strings are relatively coupled to different drain select lines.

4. The memory device according to claim 3, wherein the at least two strings are coupled in parallel between a bit line and a source line.

5. The memory device according to claim 3,
wherein each of the plurality of memory strings includes a drain select transistor, a plurality of memory cells, and the source select transistor that are coupled in series between a bit line and a source line, and
wherein the voltage generation circuit is configured to generate the turn-on voltage and applies the generated turn-on voltage to the drain select transistor and the source select transistor of an unselected string of the at least two strings during the set application period.

6. The memory device according to claim 5, wherein the voltage generation circuit is configured to apply the generated turn-on voltage to the drain select transistor and the source select transistor of the selected string of the at least two strings during a fixed application period.

7. The memory device according to claim 1, wherein the control logic is configured to control the voltage generation circuit to perform a read voltage application operation of applying a read voltage and a pass voltage to word lines of the selected string after the channel initialization operation.

8. The memory device according to claim 7, wherein the control logic is configured to control the voltage generation circuit to apply the pass voltage to the word lines during the channel initialization operation.

9. The memory device according to claim 1, wherein the voltage generation circuit comprises:
a voltage generator configured to generate the turn-on voltage in response to control of the control logic; and
an address decoder configured to apply the turn-on voltage to the plurality of strings in response to control of the control logic during the set application period.

10. A memory device comprising:
a memory cell array including a plurality of strings;
a temperature detection circuit configured to detect an internal temperature of the memory device and generate a temperature signal;
a voltage generation circuit configured to apply a turn-on voltage to select lines of a selected string and an unselected string of the plurality of strings during a channel initialization operation of a read operation; and
control logic configured to control, during the channel initialization operation, the voltage generation circuit to apply the turn-on voltage to the select lines of the selected string during a fixed application time, and apply the turn-on voltage to the select lines of the unselected strings during a variable time,
wherein the control logic is configured to vary an application time of the turn-on voltage to be applied to the unselected strings in response to the temperature signal.

11. The memory device according to claim 10, wherein, based on the temperature signal, the control logic is configured to set the application time to a relatively short time when the internal temperature of the memory device is relatively high, and sets the application time to a relatively long time when the internal temperature of the memory device is relatively low.

12. The memory device according to claim 10, wherein the plurality of strings share one source select line per at least two strings, and the at least two strings are relatively coupled to different drain select lines.

13. The storage device according to claim 12, wherein the at least two strings are coupled in parallel between a bit line and a source line.

14. The memory device according to claim 10, wherein the control logic is configured to control the voltage generation circuit to perform a read voltage application operation of applying a read voltage and a pass voltage to word lines of the selected string after the channel initialization operation.

15. The memory device according to claim 14, wherein the control logic is configured to control the voltage generation circuit to apply the pass voltage to the word lines during the channel initialization operation.

16. A method of operating a memory device, comprising:
measuring an internal temperature of the memory device;
setting a turn-on voltage application period of a channel initialization operation based on the measured internal temperature;
applying a turn-on voltage to select transistors of an unselected string among a plurality of strings during the set turn-on voltage application period; and
applying a pass voltage to word lines of the plurality of strings.

17. The method according to claim 16, wherein setting the turn-on voltage application period of the channel initialization operation based on the measured internal temperature comprises:
reducing, as the measured temperature is increased, the set application period of the turn-on voltage application period; and
increasing, as the measured temperature is reduced, the set application period of the turn-on voltage application period.

18. The method according to claim 16, wherein applying the turn-on voltage to the select transistors of the unselected string comprises applying the turn-on voltage to the select transistors of a selected string among the plurality of strings, wherein the turn-on voltage application period of the selected string is fixed regardless of the internal temperature.

19. The method according to claim 18, wherein the plurality of strings share word lines.

20. The method according to claim 19, wherein applying the turn-on voltage to the select transistors of the unselected string comprises applying a pass voltage to the word lines.
